(19) United States
(12) Patent Application Publication
(10) Pub. No.: US 2024/0321875 A1
(43) Pub. Date: Sep. 26, 2024

(54) SEMICONDUCTOR DEVICE

(71) Applicant: SAMSUNG ELECTRONICS CO., LTD., Suwon-si (KR)

(72) Inventors: Wooseok PARK, Suwon-si (KR); Jaeho Jeon, Suwon-si (KR); Donghoon Hwang, Suwon-si (KR); Taehyun Ryu, Suwon-si (KR); Namhyun Lee, Suwon-si (KR)

(21) Appl. No.: 18/603,591

(22) Filed: Mar. 13, 2024

(30) Foreign Application Priority Data
Mar. 24, 2023 (KR) 10-2023-0039148
May 15, 2023 (KR) 10-2023-0062697

(51) Int. Cl. H01L 27/088; H01L 29/06; H01L 29/423; H01L 29/775; H01L 29/786

(52) U.S. Cl. CPC H01L 27/088; H01L 29/0673; H01L 29/42392; H01L 29/775; H01L 29/78696

(57) ABSTRACT

A semiconductor device includes a substrate, an active region protruding from an upper surface of the substrate and extending in a first horizontal direction, a plurality of nanosheet stacks on the active region, a plurality of gate lines extending in a second horizontal direction intersecting the first horizontal direction, on the active region, and surrounding the plurality of nanosheet stacks, and a first insulating pattern between two nanosheet stacks adjacent in the first horizontal direction among the plurality of nanosheet stacks, on the active region, and extending in a vertical direction perpendicular to the first horizontal direction and the second horizontal direction, wherein the first insulating pattern is in contact with the plurality of nanosheet stacks.

### CROSS-REFERENCE TO RELATED APPLICATION

This application is based on and claims priority under 35 U.S.C. § 119 to Korean Patent Application Nos. 10-2023-0039148, filed on Mar. 24, 2023, and 10-2023-0062697, filed on May 15, 2023, in the Korean Intellectual Property Office, the disclosure of which is incorporated by reference herein in its entirety.

### BACKGROUND

### 1. Field

The inventive concept relates to a semiconductor device. More specifically, the inventive concept relates to a semiconductor device including a field-effect transistor.

### 2. Description of the Related Art

Owing to the development of electronic technology, the demand for high integration of semiconductor devices is increasing and downscaling thereof is in progress. According to the downscaling of semiconductor devices, a short channel effect of a transistor occurs, which causes a decrease in the reliability of integrated circuit devices. In order to reduce the short channel effect, a semiconductor device having a multi-gate structure such as a nanosheet type transistor has been proposed.

### SUMMARY

Embodiments are directed to a semiconductor device including a substrate, an active region protruding from an upper surface of the substrate and extending in a first horizontal direction, a plurality of nanosheet stacks on the active region, a plurality of gate lines on the active region and extending in a second horizontal direction intersecting the first horizontal direction, and surrounding the plurality of nanosheet stacks, and a first insulating pattern between two nanosheet stacks adjacent in the first horizontal direction among the plurality of nanosheet stacks, on the active region, and extending in a vertical direction perpendicular to the first horizontal direction and the second horizontal direction, the first insulating pattern contacting the plurality of nanosheet stacks.

Embodiments are directed to a semiconductor device having a substrate, an active region protruding from an upper surface of the substrate and extending in a first horizontal direction, an isolation insulating layer on an upper surface of the active region, a plurality of nanosheet stacks on the active region, a plurality of gate lines extending in a second horizontal direction intersecting the first horizontal direction, on the active region, and surrounding the plurality of nanosheet stacks, a first insulating pattern between two nanosheet stacks adjacent in the first horizontal direction among the plurality of nanosheet stacks, on the active region, and extending in a vertical direction perpendicular to the first horizontal direction and the second horizontal direction, the first insulating pattern in contact with the plurality of nanosheet stacks, and a second insulating pattern extending in the first horizontal direction on the active region.

Embodiments are directed to a semiconductor device having a substrate, an active region protruding from an upper surface of the substrate and extending in a first horizontal direction, a device isolation layer surrounding both sidewalls of the active region, an isolation insulating layer on an upper surface of the active region, a plurality of nanosheet stacks spaced apart from the upper surface of the active region, a plurality of gate lines extending in a second horizontal direction intersecting the first horizontal direction, on the active region, and surrounding the plurality of nanosheet stacks, a plurality of source/drain regions between the plurality of nanosheet stacks, on the active region, and contacting the plurality of nanosheet stacks, a first insulating pattern between two nanosheet stacks adjacent in the first horizontal direction among the plurality of nanosheet stacks, on the active region, and extending in a vertical direction perpendicular to the first horizontal direction and the second horizontal direction, the first insulating pattern being in contact with the plurality of nanosheet stacks and spaced apart from the plurality of source/drain regions, and a second insulating pattern extending in the first horizontal direction, on the active region, and at least partially penetrating the plurality of gate lines, the isolation insulating layer, and the active region, in the vertical direction.

Embodiments provide a semiconductor device with improved structural reliability.

### BRIEF DESCRIPTION OF THE DRAWINGS

Features will become apparent to those of skill in the art by describing in detail exemplary embodiments with reference to the attached drawings, in which:

FIG. 1 is a plan layout diagram showing some configurations of a semiconductor device according to some embodiments;

FIG. 2 is a cross-sectional view of an embodiment taken along a line X1-X1′ of FIG. 1;

FIG. 3 is a cross-sectional view of an embodiment taken along a line Y1-Y1′ of FIG. 1;

FIG. 4 is a cross-sectional view of an embodiment taken along a line corresponding to the line X1-X1′ of FIG. 1;

FIG. 5 is a cross-sectional view of an embodiment taken along a line corresponding to the line Y1-Y1′ in FIG. 1;

FIG. 6 is a cross-sectional view of an embodiment taken along a line corresponding to the line X1-X1′ of FIG. 1;

FIG. 7 is a cross-sectional view of an embodiment taken along a line corresponding to the line Y1-Y1′ of FIG. 1;

FIG. 8 is a plan layout diagram illustrating some configurations of a semiconductor device according to some embodiments;

FIG. 9 is a cross-sectional view of an embodiment taken along a line Y2-Y2′ of FIG. 8; and

FIGS. 10A, 10B, 11, 12A, 12B, 13A, 13B, 14A, 14B, 15, 16A, 16B, 16C, 17A, 17B, 17C, 18A, 18B, 18C, 19A, 19B, 20A, 20B, 21A, 21B, 22, 23, and 24 are diagrams for explaining a method of manufacturing a semiconductor device according to some embodiments.

### DETAILED DESCRIPTION

Hereinafter, embodiments of the inventive concept will be described in detail with reference to the accompanying drawings. The same reference numerals are used for the same components in the drawings, and redundant descriptions thereof are omitted.

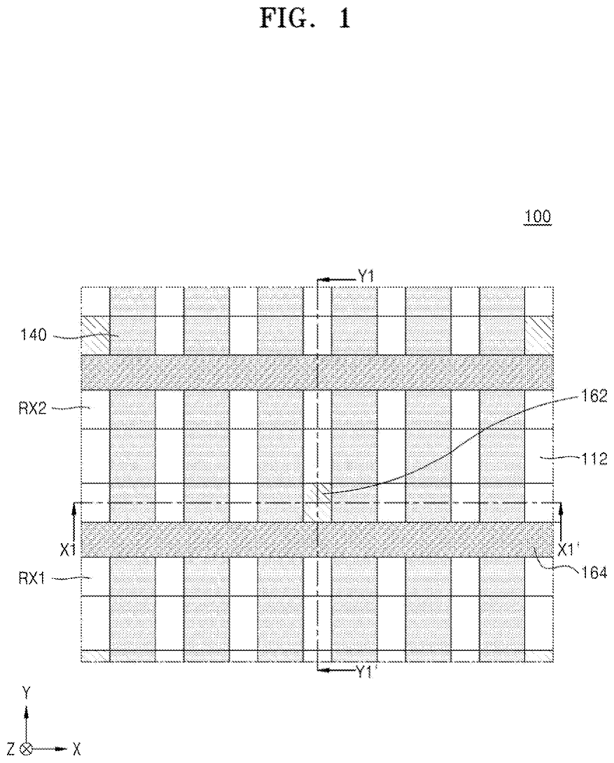

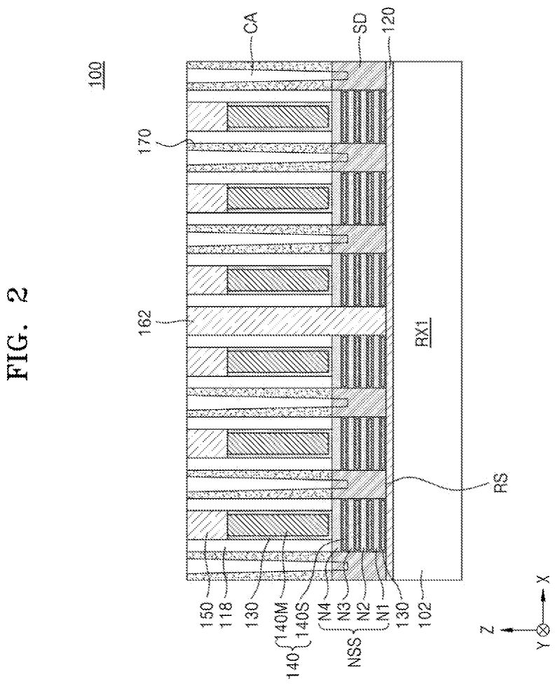

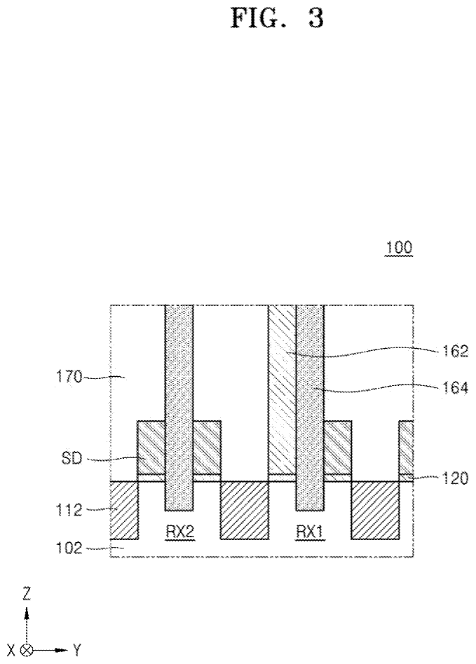

FIG. 1 is a plan layout diagram showing some configurations of a semiconductor device 100 according to some embodiments. FIG. 2 is a cross-sectional view taken along a line X1-X1′ of FIG. 1. FIG. 3 is a cross-sectional view taken along a line Y1-Y1′ of FIG. 1.

Referring to FIGS. 1 to 3, the semiconductor device 100 may include a substrate 102 including a plurality of active regions RX1 and RX2, a plurality of nanosheet stacks NSS on the plurality of active regions RX1 and RX2, a plurality of gate lines 140 surrounding the plurality of nanosheet stacks NSS on the plurality of active regions RX1 and RX2, a first insulating pattern 162 on at least a part between the plurality of nanosheet stacks NSS on the plurality of active regions RX1 and RX2, and a second insulating pattern 164 extending in a first horizontal direction (X direction) on the plurality of active regions RX1 and RX2.

The substrate 102 may include the plurality of active regions RX1 and RX2 protruding in a vertical direction (Z direction). The plurality of active regions RX1 and RX2 may extend parallel to each other in the first horizontal direction (X direction). The plurality of active regions RX1 and RX2 may include a first active region RX1 and a second active region RX2.

The substrate 102 may include a group IV semiconductor such as silicon (Si) or germanium (Ge), a group IV-IV compound semiconductor such as silicon-germanium (SiGe) or silicon carbide (SiC), or a group III-V compound semiconductor such as gallium arsenide (GaAs), indium arsenide (InAs) or indium phosphide (InP). As used herein, the terms “SiGe”, “SiC”, “GaAs”, “InAs”, and “InP” mean materials including elements included in the terms, and are not chemical equations exhibiting a stoichiometric relationship. The substrate 102 may include a conductive region, e.g., a well doped with impurities or a structure doped with impurities.

A device isolation layer 112 covering both sidewalls of each of the plurality of active regions RX1 and RX2 may be on the substrate 102. The device isolation layer 112 may include, e.g., an oxide layer, a nitride layer, or a combination thereof.

The isolation insulating layer 120 may be on upper surfaces of the plurality of active regions RX1 and RX2 of the substrate 102. An isolation insulating layer 120 may extend long in the first horizontal direction (X direction) on the plurality of active regions RX1 and RX2. The isolation insulating layer 120 may include, e.g., a silicon nitride layer.

The plurality of gate lines 140 may extend long in a second horizontal direction (Y direction) intersecting the first horizontal direction (X direction) on the plurality of active regions RX1 and RX2. In regions where the plurality of active regions RX1 and RX2 and the plurality of gate lines 140 cross each other, the plurality of nanosheet stacks NSS may be on each of the plurality of active regions RX1 and RX2. As used herein, the term “nanosheet” refers to a conductive structure having a cross section substantially perpendicular to a direction in which current flows. It should be understood that the nanosheet includes nanowires.

Each of the plurality of nanosheet stacks NSS may include a plurality of nanosheets N1, N2, N3, and N4 spaced apart from each other from an upper surface of each of the plurality of active regions RX1 and RX2 in the vertical direction (Z direction). The plurality of nanosheets N1, N2, N3, and N4 may have different vertical direction lengths (Z direction distances) from the upper surface of each of the plurality of active regions RX1 and RX2. The plurality of nanosheets N1, N2, N3, and N4 may include a first nanosheet N1, a second nanosheet N2, a third nanosheet N3, and a fourth nanosheet N4 sequentially stacked on the upper surface of each of the plurality of active regions RX1 and RX2. Each of the plurality of nanosheets N1, N2, N3, and N4 may include the group IV semiconductor such as Si or Ge, the group IV-IV compound semiconductor such as SiGe or SiC, or the group III-V compound such as GaAs, InAs, or InP.

The number of each of the plurality of nanosheet stacks NSS and the plurality of gate lines 140 on the plurality of active regions RX1 and RX2 is not particularly limited. In an implementation, one or the plurality of nanosheet stacks NSS and one or the plurality of gate lines 140 may be on each of the plurality of active regions RX1 and RX2.

FIGS. 1 to 3 illustrate that each of the plurality of nanosheet stacks NSS includes the four nanosheets N1, N2, N3, and N4, but the inventive concept is not limited thereto, and nanosheets are not limited thereto. The number of nanosheets included in the plurality of nanosheet stacks NSS is not particularly limited. In an implementation, each of the plurality of nanosheet stacks NSS may include one, two, or three or more nanosheets. Each of the plurality of nanosheets N1, N2, N3, and N4 may include a channel region. In some embodiments, the plurality of nanosheets N1, N2, N3, and N4 may have substantially the same thickness in the vertical direction (Z direction). In some embodiments, at least some of the plurality of nanosheets N1, N2, N3, and N4 may have different thicknesses in the vertical direction (Z direction).

As illustrated in FIGS. 1 to 3, the plurality of nanosheets N1, N2, N3, and N4 included in each of the plurality of nanosheet stacks NSS may have the same size in the first horizontal direction (X direction). In some embodiments, at least some of the plurality of nanosheets N1, N2, N3, and N4 included in each of the plurality of nanosheet stacks NSS have different sizes in the first horizontal direction (X direction). In an implementation, among the plurality of nanosheets N1, N2, N3, and N4 in the first horizontal direction (X direction), a length of each of the first nanosheet N1 and the second nanosheet N2 relatively close to the upper surfaces of the plurality of active regions RX1 and RX2 may be smaller than a length of each of the third nanosheet N3 and the fourth nanosheet N4 relatively far from the upper surfaces of the plurality of active regions RX1 and RX2.

A plurality of recesses RS may be formed in an upper surface of the isolation insulating layer 120 on the plurality of active regions RX1 and RX2. A plurality of source/drain regions SD may be respectively formed on the plurality of recesses RS. Each of the plurality of source/drain regions SD may be connected to both ends of the nanosheet stack NSS. The plurality of source/drain regions SD may have, e.g., a vertical cross-sectional shape such as a hexagon, a pentagon, a rhombus, or a polygon with rounded corners. In some embodiments, each of the plurality of source/drain regions SD may include a doped Si film, a doped SiGe film, a doped Ge film, a doped SiC film, or a doped InGaAs film, but is limited thereto. In some embodiments, each of the plurality of source/drain regions SD may include a plurality of semiconductor layers having different compositions from each other. In an implementation, each of the plurality of source/drain regions SD may include a lower semiconductor layer (not shown), an upper semiconductor layer (not shown), and a capping semiconductor layer (not shown) sequentially filling the recess RS. In an implementation, the lower semiconductor layer, the upper semiconductor layer, and the capping semiconductor layer may each include SiC and have different Si and C contents.

The plurality of gate lines 140 may extend long in the second horizontal direction (Y direction) on the plurality of active regions RX1 and RX2 and the device isolation layer 112. The plurality of gate lines 140 may be spaced apart from each other in the first horizontal direction (X direction). The plurality of gate lines 140 may surround each of the plurality of nanosheets N1, N2, N3, and N4 while covering the plurality of nanosheet stacks NSS on the plurality of active regions RX1 and RX2. A plurality of transistors may be formed in portions where the plurality of active regions RX1 and RX2 and the plurality of gate lines 140 cross each other on the substrate 102. In some embodiments, the first active region RX1 may be a PMOS transistor region, and the second active region RX2 may be an NMOS transistor region. In this case, a plurality of PMOS transistors may be formed in the portions where the first active region RX1 and the plurality of gate lines 140 cross each other, and a plurality of NMOS transistors may be formed in the portions where the second active region RX2 and the plurality of gate lines 140 cross each other.

Each of the plurality of gate lines 140 may include a main gate line 140M and a plurality of sub gate lines 140S. The main gate line 140M may extend long in the second horizontal direction (Y direction) while covering the upper surface of the nanosheet stack NSS. The plurality of sub gate lines 140S may be integrally connected to the main gate line 140M, and each may be between the plurality of nanosheets N1, N2, N3, and N4 and between the plurality of active regions RX1 and RX2 and the first nanosheet N1.

Each of the plurality of gate lines 140 may include doped polysilicon, metal, conductive metal nitride, conductive metal carbide, conductive metal silicide, or a combination thereof. In an implementation, the plurality of gate lines 140 may include Al, Cu, Ti, Ta, W, Mo, TaN, NiSi, CoSi, TiN, WN, TiAl, TiAIN, TaCN, TaC, TaSiN, or a combination thereof, but is not limited thereto.

In some embodiments, the plurality of gate lines 140 may include a work function metal-containing layer (not shown) and a gap-fill metal layer (not shown). The work function metal-containing layer may include at least one metal selected from Ti, W, Ru, Nb, Mo, Hf, Ni, Co, Pt, Yb, Tb, Dy, Er, and Pd. The gap-fill metal layer may include a W layer or an Al layer. In some embodiments, the plurality of gate lines 140 may include a stacked structure of TiAlC/TiN/W, a stacked structure of TiN/TaN/TiAlC/TiN/W, or a stacked structure of TiN/TaN/TiN/TiAlC/TiN/W, but is not limited thereto.

A gate insulating layer 130 may be between the plurality of nanosheets N1, N2, N3, and N4 and the gate line 140. The gate insulating layer 130 may include a part covering a surface of each of the plurality of nanosheets N1, N2, N3, and N4 and a part covering sidewalls of the main gate line 140M.

In some embodiments, the gate insulating layer 130 may include a silicon oxide layer, a silicon oxynitride layer, a high-k dielectric layer having a higher dielectric constant than the silicon oxide layer, or a combination thereof. The high dielectric layer may include metal oxide or metal oxynitride. In an implementation, the high dielectric layer may include HfO2, HfSiO, HfSiON, HfTaO, HfTiO, HfZrO, ZrO2, Al2O3, or a combination thereof, but is not limited thereto.

A gate capping layer 150 may be on the main gate line 140M and the gate insulating layer 130 covering sidewalls of the main gate line 140M. The gate capping layer 150 may cover the main gate line 140M and the gate insulating layer 130 covering sidewalls of the main gate line 140M. The gate capping layer 150 may extend long in the second horizontal direction (Y direction) on the main gate line 140M and the gate insulating layer 130 covering sidewalls of the main gate line 140M. In some embodiments, the gate capping layer 150 may include silicon nitride or silicon oxynitride.

A gate spacer 118 may be on both sidewalls of the main gate line 140M and both sidewalls of the gate capping layer 150. The gate spacer 118 may cover both sidewalls of the main gate line 140M and both sidewalls of the gate capping layer 150. The gate spacer 118 may extend long in the second horizontal direction (Y direction) on the substrate 102. The gate spacer 118 may be spaced apart from the main gate electrode 140M with the gate insulating layer 130 therebetween.

In some embodiments, the gate spacer 118 may include silicon oxide, silicon nitride, silicon oxynitride, silicon carbonitride, silicon oxycarbonitride, or a combination thereof.

An inter-gate insulating layer 170 may be on the plurality of source/drain regions SD and the device isolation layer 112. The inter-gate insulating layer 170 may cover upper surfaces of the plurality of source/drain regions SD and an upper surface of the device isolation layer 112. In some embodiments, the inter-gate insulating layer 170 may include silicon oxide, silicon carbon oxide, or silicon oxynitride.

A plurality of source/drain contacts CA may be respectively on the plurality of source/drain regions SD. The plurality of source/drain contacts CA may respectively extend in the vertical direction (Z direction) through the inter-gate insulating layer 170 and at least a part of the plurality of source/drain regions SD. However, the inventive concept is not limited thereto, and unlike shown in FIG. 2, the plurality of source/drain contacts CA each may extend in the vertical direction (Z direction) through the inter-gate insulating layer 170, and bottom surfaces of the plurality of source/drain contacts CA may respectively contact upper surfaces of the plurality of source/drain regions SD. The plurality of source/drain regions SD may be respectively connected to upper conductive lines (not shown) through the plurality of source/drain contacts CA corresponding thereto so as to overlap in the vertical direction (Z direction).

Each of the plurality of source/drain contacts CA may include a contact plug (not shown) and a conductive barrier layer (not shown) covering the contact plug. The contact plug may include at least one of tungsten (W), cobalt (Co), molybdenum (Mo), nickel (Ni), ruthenium (Ru), copper (Cu), aluminum (Al), a silicide thereof, or an alloy thereof. The conductive barrier layer may include at least one of ruthenium (Ru), titanium (Ti), titanium nitride (TiN), tantalum (Ta), tantalum nitride (TaN), tungsten (W), titanium silicon nitride (TiSiN), titanium silicide (TiSi), or tungsten silicide (WSi).

A plurality of gate contacts (not shown) may be respectively formed on the plurality of gate lines 140. The plurality of gate lines 140 may be respectively connected to upper conductive lines (not shown) through the plurality of gate contacts. The plurality of gate contacts may respectively have structures similar to those of the plurality of source/drain contacts CA described above.

The first insulating pattern 162 may be on at least a part between the plurality of nanosheet stacks NSS on the plurality of active regions RX1 and RX2. In an implementation, the first insulating pattern 162 may be between two nanosheet stacks NSS adjacent in the first horizontal direction (X direction) among the plurality of nanosheet stacks NSS on the plurality of active regions RX1 and RX2. In some embodiments, the first insulating pattern 162 may be on at least some and may not be on the others between two nanosheet stacks NSS adjacent in the first horizontal direction (X direction) among the plurality of nanosheet stacks NSS on the plurality of active regions RX1 and RX2 Accordingly, a separation distance between the first insulating patterns 162 in the first horizontal direction (X direction) may be greater than a separation distance between the plurality of nanosheet stacks NSS in the first horizontal direction (X direction). In some embodiments, the first insulating pattern 162 may be arranged in a zigzag or matrix form on the plurality of active regions RX1 and RX2.

In some embodiments, the entire first insulating pattern 162 may overlap the plurality of active regions RX1 and RX2 in the vertical direction (Z direction). That is, the first insulating pattern 162 may not be beyond the plurality of active regions RX1 and RX2 in the second horizontal direction (Y direction).

In some embodiments, the first insulating pattern 162 may extend in the vertical direction (Z direction) on the upper surface of the isolation insulating layer 120. In an implementation, the first insulating pattern 162 may extend in the vertical direction (Z direction) from the upper surface of the isolation insulating layer 120 to the same vertical level as the upper surface of the gate capping layer 150. A bottom surface of the first insulating pattern 162 may contact an upper surface of the isolation insulating layer 120. An upper surface of the first insulating pattern 162 may be positioned at substantially the same vertical level as the upper surface of the gate capping layer 150.

In some embodiments, upper portions of both sidewalls of the first insulating pattern 162 facing each other in the first horizontal direction (X direction) may contact a gate spacer 118 covering both sidewalls of each of the two gate lines 140, and lower portions of both sidewalls may contact the nanosheet stack NSS. The first insulating pattern 162 may be spaced apart from the plurality of source/drain regions SD in the first horizontal direction (X direction) by the plurality of nanosheet stacks NSS and the plurality of gate lines 140. In some embodiments, one sidewall of both sidewalls of the first insulating pattern 162 facing each other in the second horizontal direction (Y direction) may contact the inter-gate insulating layer 170, and the other sidewall facing one sidewall in the second horizontal direction (Y direction) may contact the second insulating pattern 164.

The first insulating pattern 162 may electrically insulate two transistors adjacent in the first horizontal direction (X direction) among the plurality of transistors respectively formed at the portions where the plurality of active regions RX1 and RX2 and the plurality of gate lines 140 intersect each other.

The second insulating pattern 164 may extend long in the first horizontal direction (X direction) on the plurality of active regions RX1 and RX2. The second insulating pattern 164 may at least partially penetrate the plurality of gate lines 140, the plurality of nanosheet stacks NSS, the isolation insulating layer 120, and the plurality of active regions RX1 and RX2 in the vertical direction (Z direction).

In some embodiments, an upper surface of the first insulating pattern 162 and an upper surface of the second insulating pattern 164 may be positioned on the same vertical level. In some embodiments, a bottom surface of the first insulating pattern 162 may be positioned at a higher vertical level than a bottom surface of the second insulating pattern 164.

The second insulating pattern 164 may electrically insulate two transistors adjacent in the second horizontal direction (Y direction) among the plurality of transistors respectively formed at the portions where the plurality of active regions RX1 and RX2 and the plurality of gate lines 140 intersect each other.

In some embodiments, the first insulating pattern 162 and the second insulating pattern 164 may include silicon nitride, silicon carbonitride, silicon carbonate, or silicon carbonitride.

In some embodiments, the first insulating pattern 162 and the second insulating pattern 164 may include different materials. In an implementation, the first insulating pattern 162 may include silicon carbonate and the second insulating pattern 164 may include silicon nitride.

In some embodiments, the first insulating pattern 162 may include a material different from that of the isolation insulating layer 120. In an implementation, the first insulating pattern 162 may include silicon nitride, and the isolation insulating layer 120 may include silicon carbonitride.

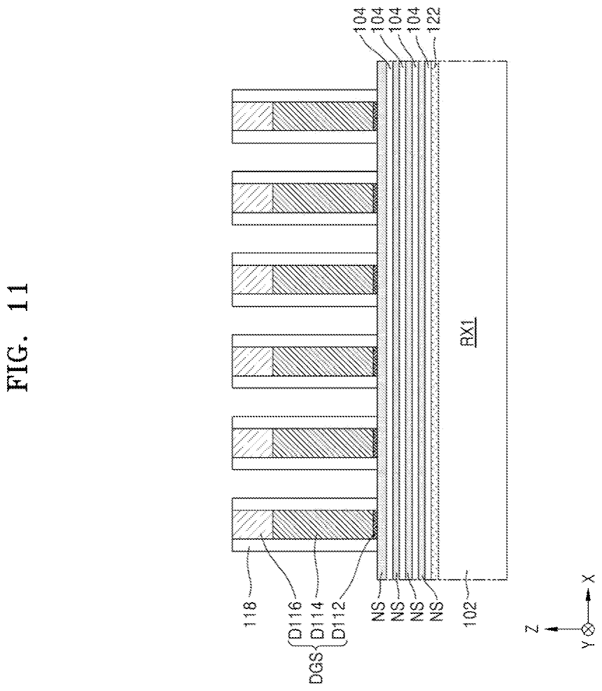

The semiconductor device 100 according to some embodiments may include the first insulating pattern 162 electrically insulating two transistors adjacent in the first horizontal direction (X direction). The first insulating pattern 162 is formed after the plurality of recesses RS are formed, and thus, a dummy gate structure DGS (e.g., in FIG. 11) formed before the plurality of recesses RS is formed during a manufacturing process of the semiconductor device 100 may prevent leaning due to stress of the first insulating pattern 162. Accordingly, when a process of forming the plurality of recesses RS is performed, a distribution of the plurality of recesses RS in the vertical direction length (the Z direction length) which may occur due to leaning of the dummy gate structure DGS may be improved. Moreover, a distribution of the plurality of transistors including the plurality of source/drain regions SD respectively formed in the plurality of recesses RS is improved, and thus, the structural reliability of the semiconductor device 100 may be improved.

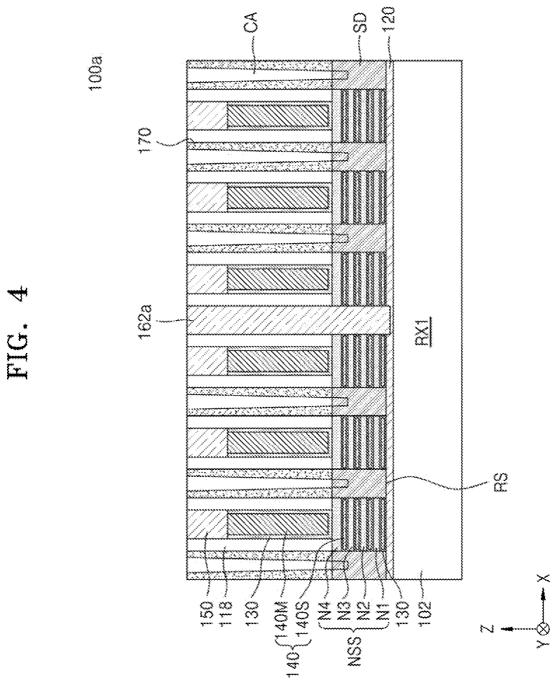

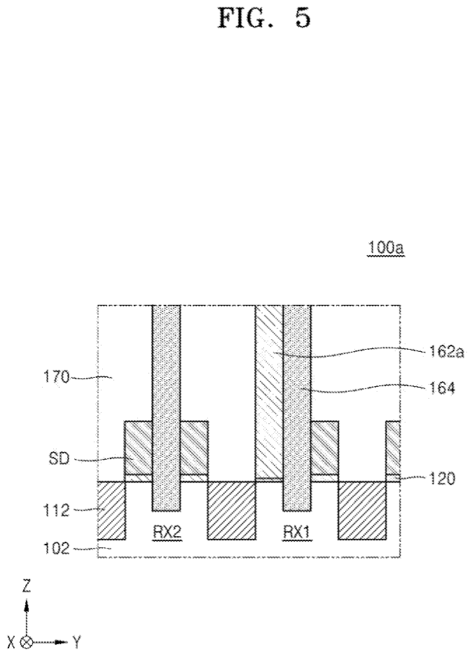

FIG. 4 is a cross-sectional view of an embodiment taken along a line corresponding to the line X1-X1′ of FIG. 1. FIG. 5 is a cross-sectional view of an embodiment taken along a line corresponding to the line Y1-Y1′ in FIG. 1. Each configuration of a semiconductor device 100a illustrated in FIGS. 4 and 5 is similar to each configuration of the semiconductor device 100 described with reference to FIGS. 1 to 3, and thus, hereinafter, differences are mainly described.

Referring to FIGS. 4 and 5, the semiconductor device 100a may include the substrate 102 including the plurality of active regions RX1 and RX2, the plurality of nanosheet stacks NSS on the plurality of active regions RX1 and RX2, the plurality of gate lines 140 surrounding the plurality of nanosheet stacks NSS on the plurality of active regions RX1 and RX2, a first insulating pattern 162a on at least a part between the plurality of nanosheet stacks NSS on the plurality of active regions RX1 and RX2, and the second insulating pattern 164 extending in the first horizontal direction (X direction) on the plurality of active regions RX1 and RX2.

The first insulating pattern 162a may be on at least a part between the plurality of nanosheet stacks NSS on the plurality of active regions RX1 and RX2. In some embodiments, the first insulating pattern 162a may extend into the isolation insulating layer 120. Accordingly, a bottom surface of the first insulating pattern 162a may be positioned at a vertical level between an upper surface and a lower surface of a part of the isolation insulating layer 120 not overlapping the first insulating pattern 162a in the vertical direction (Z direction).

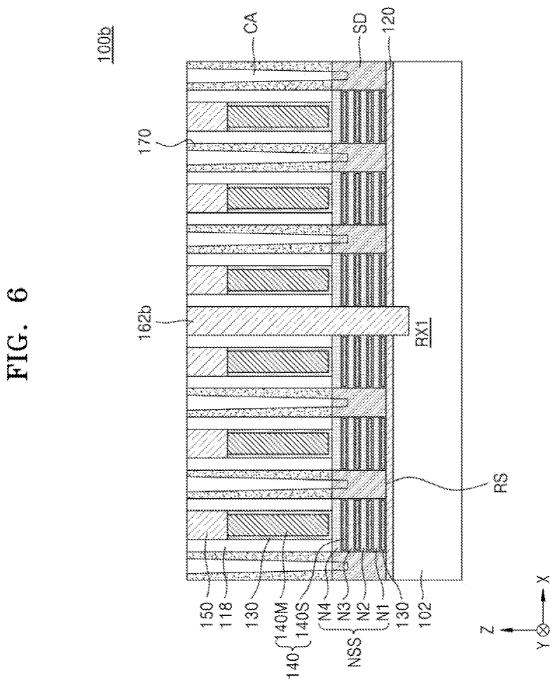

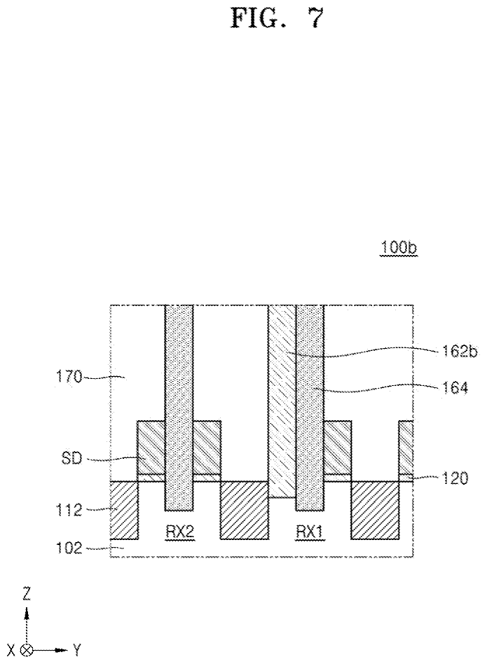

FIG. 6 is a cross-sectional view of an embodiment taken along a line corresponding to the line X1-X1′ of FIG. 1. FIG. 7 is a cross-sectional view of an embodiment taken along a line corresponding to the line Y1-Y1′ of FIG. 1. Each configuration of a semiconductor device 100b illustrated in FIGS. 6 and 7 is similar to each configuration of the semiconductor device 100 described with reference to FIGS. 1 to 3, and thus, hereinafter, differences are mainly described.

Referring to FIGS. 6 and 7, the semiconductor device 100b may include the substrate 102 including the plurality of active regions RX1 and RX2, the plurality of nanosheet stacks NSS on the plurality of active regions RX1 and RX2, the plurality of gate lines 140 surrounding the plurality of nanosheet stacks NSS on the plurality of active regions RX1 and RX2, a first insulating pattern 162b on at least a part between the plurality of nanosheet stacks NSS on the plurality of active regions RX1 and RX2, and the second insulating pattern 164 extending in the first horizontal direction (X direction) on the plurality of active regions RX1 and RX2.

The first insulating pattern 162b may be on at least a part between the plurality of nanosheet stacks NSS on the plurality of active regions RX1 and RX2. In some embodiments, the first insulating pattern 162b may completely penetrate the isolation insulating layer 120 and extend in the vertical direction (Z direction). Accordingly, a bottom surface of the first insulating pattern 162b may contact upper surfaces of the plurality of active regions RX1 and RX2. In some embodiments, the first insulating pattern 162b may penetrate the isolation insulating layer 120 in the vertical direction (Z direction) and extend into the plurality of active regions RX1 and RX2. Accordingly, the upper surface of a part of the plurality of active regions RX1 and RX2 overlapping the first insulating pattern 162b in the vertical direction (Z direction) may be positioned at a lower vertical level than the upper surface of the other part of the plurality of active regions RX1 and RX2.

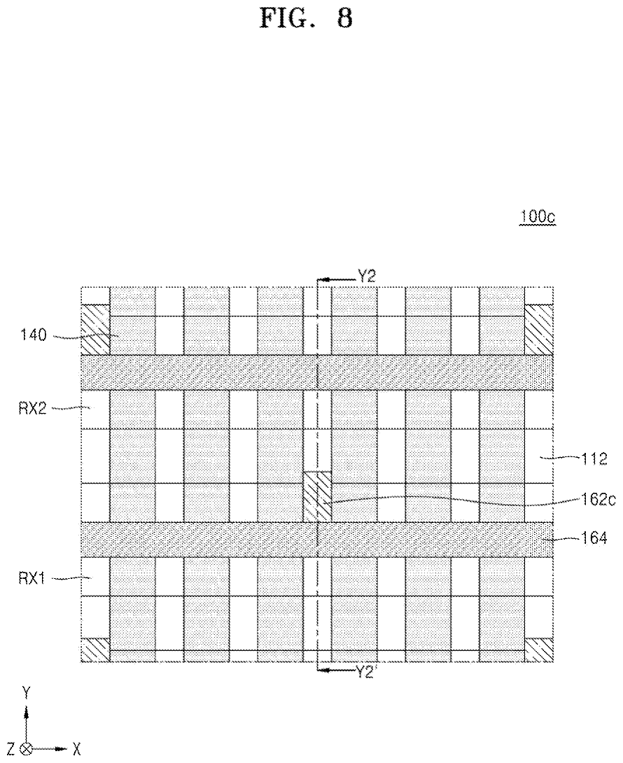

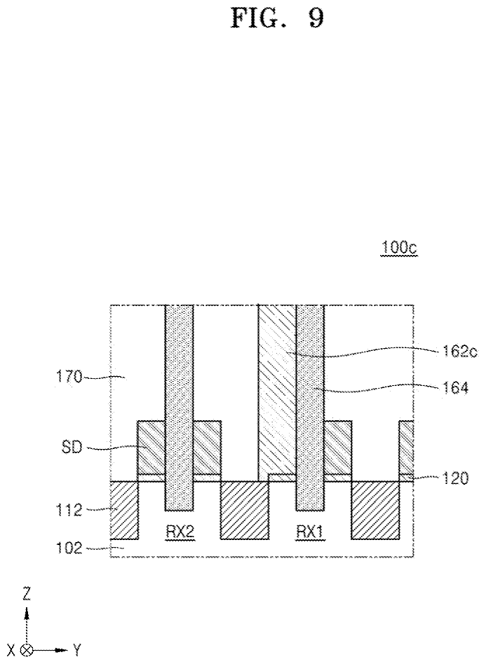

FIG. 8 is a plan layout diagram illustrating some configurations of a semiconductor device according to some embodiments. FIG. 9 is a cross-sectional view taken along a line Y2-Y2′ of FIG. 8. Each configuration of a semiconductor device 100c illustrated in FIGS. 8 and 9 is similar to each configuration of the semiconductor device 100 described with reference to FIGS. 1 to 3, and thus, hereinafter, differences are mainly described.

Referring to FIGS. 8 and 9, the semiconductor device 100c may include the substrate 102 including the plurality of active regions RX1 and RX2, the plurality of nanosheet stacks NSS on the plurality of active regions RX1 and RX2, the plurality of gate lines 140 surrounding the plurality of nanosheet stacks NSS on the plurality of active regions RX1 and RX2, a first insulating pattern 162c on at least a part between the plurality of nanosheet stacks NSS on the plurality of active regions RX1 and RX2, and the second insulating pattern 164 extending in the first horizontal direction (X direction) on the plurality of active regions RX1 and RX2.

The first insulating pattern 162c may be on at least a part between the plurality of nanosheet stacks NSS on the plurality of active regions RX1 and RX2. In some embodiments, the first insulating pattern 162c may extend in the second horizontal direction (Y direction) beyond the plurality of active regions RX1 and RX2 in a planar view. Accordingly, a part of the first insulating pattern 162c may overlap the plurality of active regions RX1 and RX2 in the vertical direction (Z direction), and the other part of the first insulating pattern 162c may overlap the device isolation layer 112 in the vertical direction (Z direction). The part of the first insulating pattern 162c overlapping the plurality of active regions RX1 and RX2 in the vertical direction (Z direction) may contact the isolation insulating layer 120, and the other part of the first insulating pattern 162c overlapping the device isolation layer 112 in the vertical direction (Z direction) may contact the device isolation layer 112. Accordingly, a bottom surface of the part of the first insulating pattern 162c overlapping the plurality of active regions RX1 and RX2 in the vertical direction (Z direction) may be positioned at a higher vertical level than a bottom surface of the other part of the first insulating pattern 162c overlapping the device isolation layer 112 in the vertical direction (Z direction).

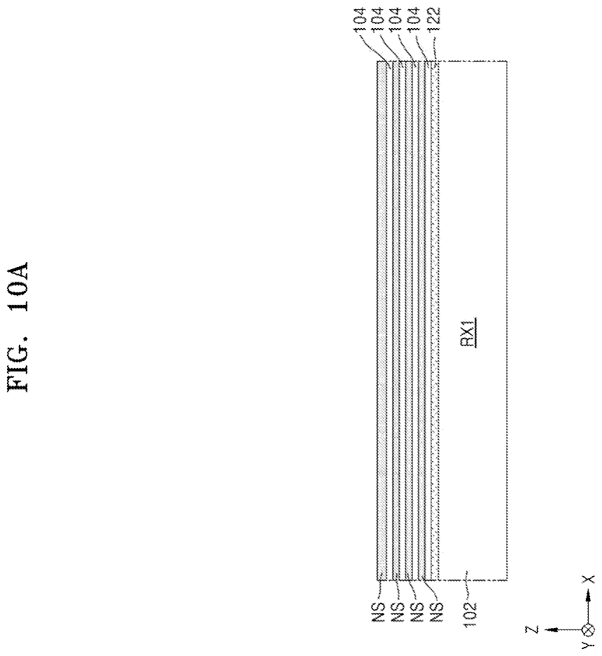

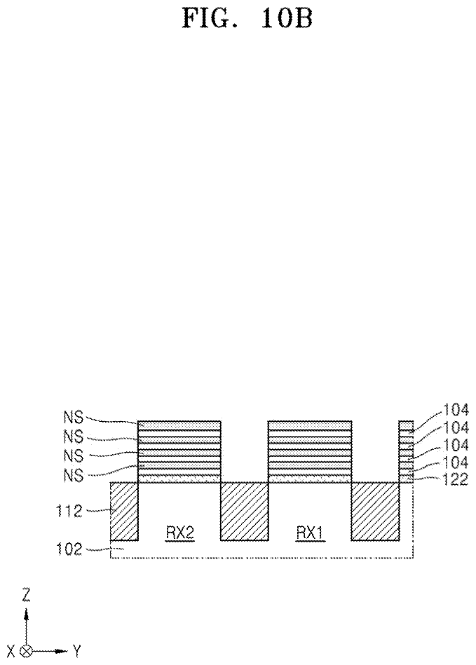

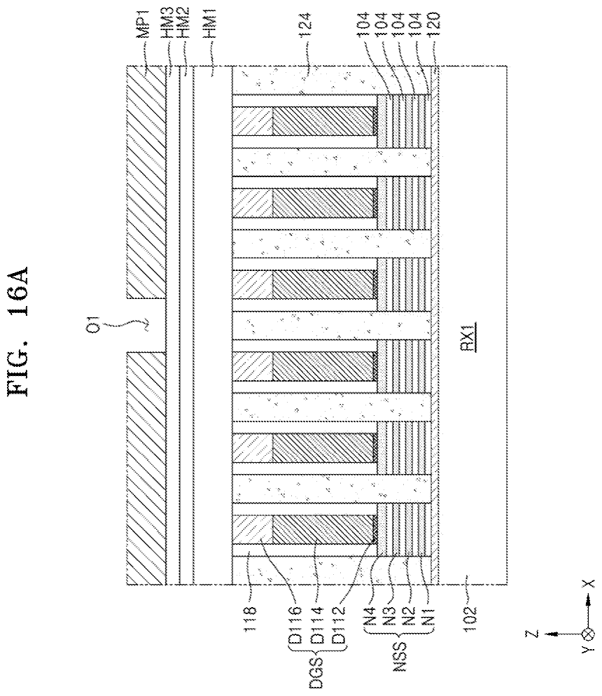

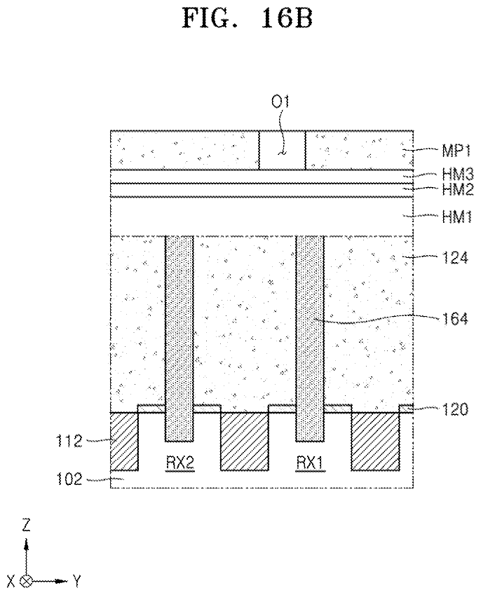

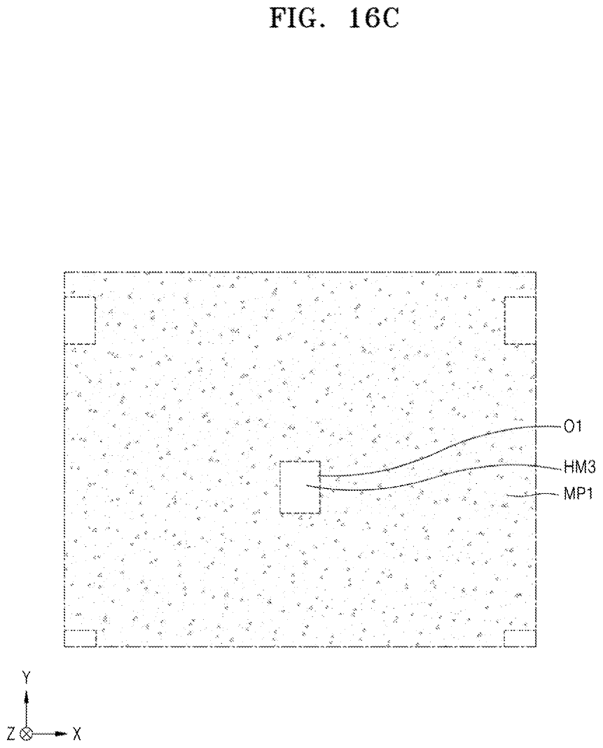

FIGS. 10A, 10B, 11, 12A, 12B, 13A, 13B, 14A, 14B, 15, 16A, 16B, 16C, 17A, 17B, 17C, 18A, 18B, 18C, 19A, 19B, 20A, 20B, 21A, 21B, 22, 23, and 24 are diagrams for explaining a method of manufacturing the semiconductor device 100 according to some embodiments. Specifically, FIGS. 10A, 11, 12A, 13A, 14A, 16A, 17A, 18A, 19A, 20A, 21A, 22, 23, and 24 are cross-sectional views taken along the line X1-X1′ of FIG. 1, FIGS. 10B, 12B, 13B, 14B, 15, 16B, 17B, 18B, 19B, 20B, and 21B are cross-sectional views taken along the line Y1-Y1′ of FIG. 1, and FIGS. 16C, 17C, and 18C are plan views for explaining the method of manufacturing the semiconductor device 100.

Referring to FIGS. 10A and 10B, after forming a first sacrificial insulating layer 122 on the substrate 102, a plurality of sacrificial semiconductor layers 104 and a plurality of nanosheet semiconductor layers NS may be alternately stacked on the first sacrificial insulating layer 122. Next, the plurality of active regions RX1 and RX2 protruding from the substrate 102 in the vertical direction (Z direction) and extending parallel to each other in the first horizontal direction (X direction) may be formed by etching a part of each of the substrate 102, the first sacrificial insulating layer 122, the plurality of sacrificial semiconductor layers 104, and the plurality of nanosheet semiconductor layers NS, and the device isolation layer 112 covering both sidewalls of each of the plurality of active regions RX1 and RX2 may be formed. An upper surface of the device isolation layer 112 may be positioned at the same or similar vertical level as an upper surface of each of the plurality of active regions RX1 and RX2.

A stacked structure of the first sacrificial insulating layer 122, the plurality of sacrificial semiconductor layers 104, and the plurality of nanosheet semiconductor layers NS may remain on the upper surface of each of the plurality of active regions RX1 and RX2. The first sacrificial insulating layer 122 may include, e.g., a SiGe layer. The plurality of sacrificial semiconductor layers 104 and the plurality of nanosheet semiconductor layers NS may include semiconductor materials having different etching selectivity. In some embodiments, the plurality of nanosheet semiconductor layers NS may include Si layers, and the plurality of sacrificial semiconductor layers 104 may include SiGe layers.

Referring to FIG. 11, from the results of FIGS. 10A and 10B, the plurality of dummy gate structures DGS and the gate spacer 118 covering both sidewalls of each of the plurality of dummy gate structures DGS may be formed on the stacked structure of the first sacrificial insulating layer 122, the plurality of sacrificial semiconductor layers 104, and the plurality of nanosheet semiconductor layers NS. Each of the plurality of dummy gate structures DGS may have a structure in which an oxide layer D112, a dummy gate layer D114, and a dummy capping layer D116 are sequentially stacked. In some embodiments, the dummy gate layer D114 may include polysilicon, and the dummy capping layer D116 may include silicon nitride.

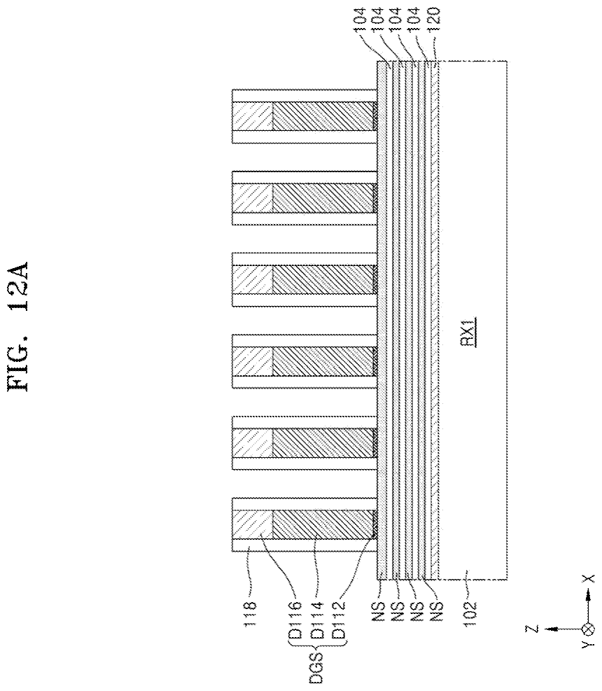

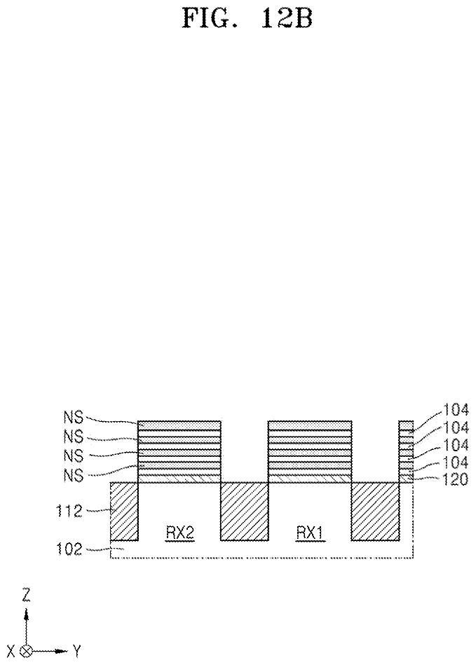

Referring to FIGS. 12A and 12B, from the result of FIG. 11, the isolation insulating layer 120 may be formed by removing the first sacrificial insulating layer 122 (see FIG. 11) and filling an insulating layer in a space where the first sacrificial insulating layer 122 is removed. In an embodiment, the isolation insulating layer 120 may include silicon oxide, silicon nitride, silicon carbonitride, silicon carbonate, or silicon carbonitride.

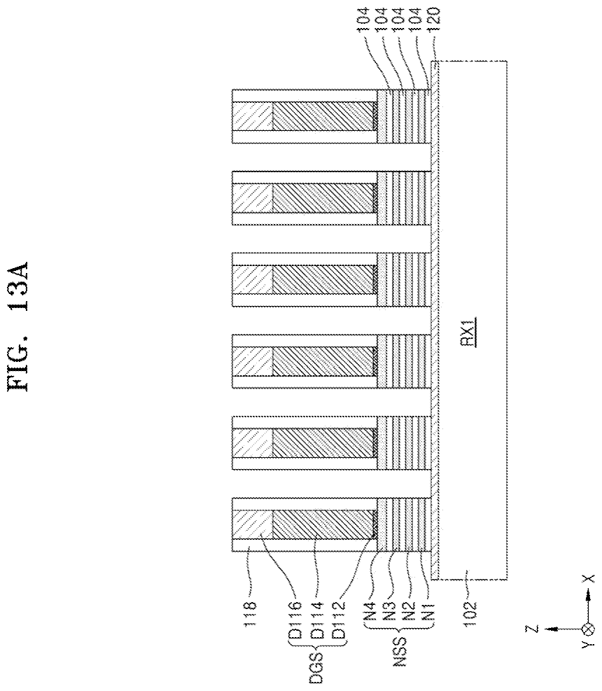

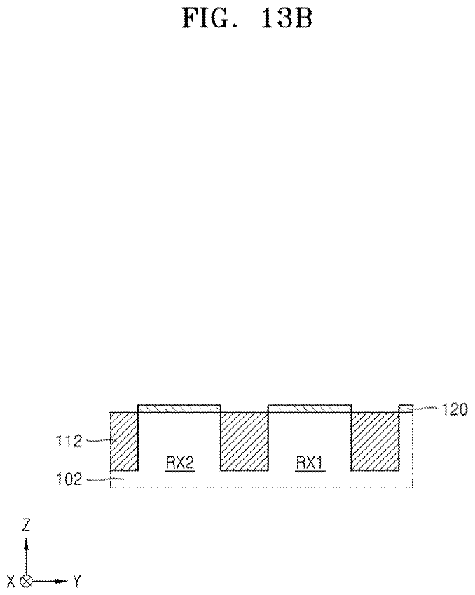

Referring to FIGS. 13A and 13B, from the results of FIGS. 12A and 12B, the plurality of nanosheet stacks NSS may be formed from the plurality of nanosheet semiconductor layers NS, by removing a part of each of the isolation insulating layer 120, the plurality of sacrificial semiconductor layers 104, and the plurality of nanosheet semiconductor layers NS (FIG. 12A) by using the plurality of dummy gate structures DGS and the gate spacer 118 as an etch mask. The plurality of nanosheet stacks NSS may include the first to fourth nanosheets N1, N2, N3, and N4.

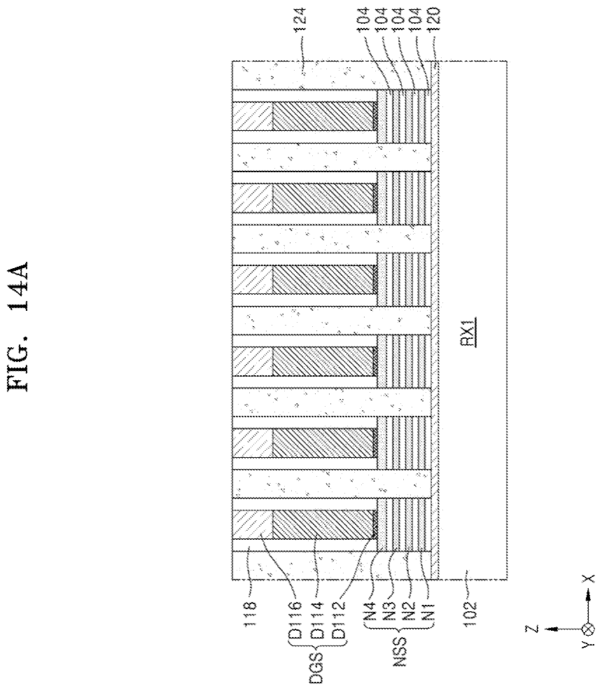

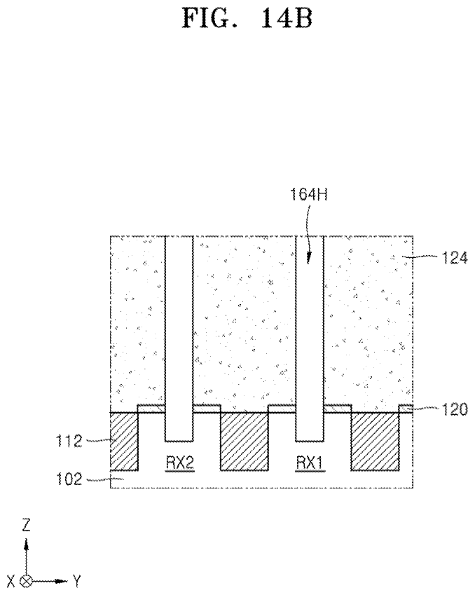

Referring to FIGS. 14A and 14B, from the results of FIGS. 13A and 13B, a second sacrificial insulating layer 124 covering an upper surface of the device isolation layer 112 and an upper surface of the isolation insulating layer 120 and surrounding the plurality of dummy gate structures DGS, the gate spacer 118, and the plurality of nanosheet stacks NSS may be formed. In some embodiments, the second sacrificial insulating layer 124 may include silicon oxide.

Next, a plurality of through holes 164H penetrating a part of each of the isolation insulating layer 120, the plurality of active regions RX1 and RX2, the second sacrificial insulating layer 124, the plurality of dummy gate structures DGS, the gate spacer 118, the plurality of sacrificial semiconductor layers 104, and the plurality of nanosheet stacks NSS in the vertical direction (Z direction) on the plurality of active regions RX1 and RX2 may be formed. Each of the plurality of through holes 164H may extend long in the second horizontal direction (Y direction).

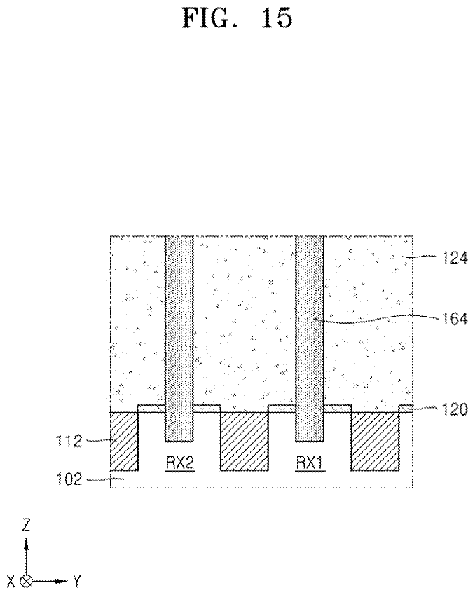

Referring to FIG. 15, from the results of FIGS. 14A and 14B, the second insulating pattern 164 may be formed by filling the plurality of through holes 164H with insulating materials. The second insulating pattern 164 may include, e.g., silicon oxide, silicon nitride, silicon carbonitride, silicon carbonate, or silicon carbonnitride.

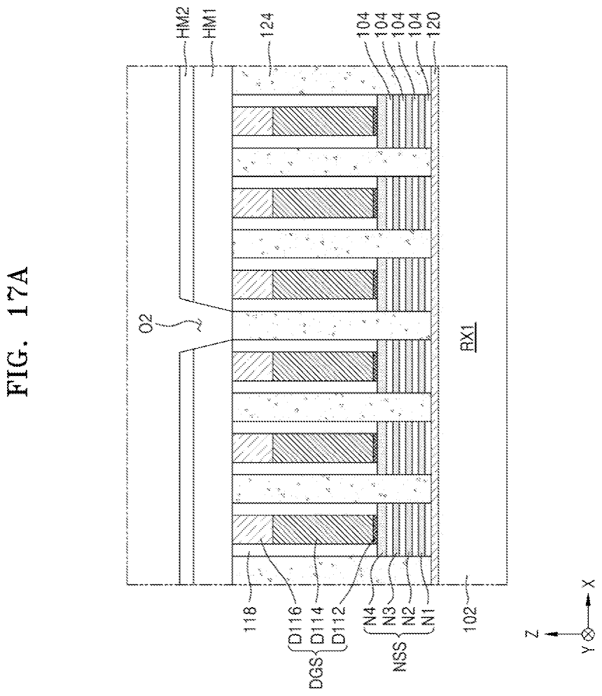

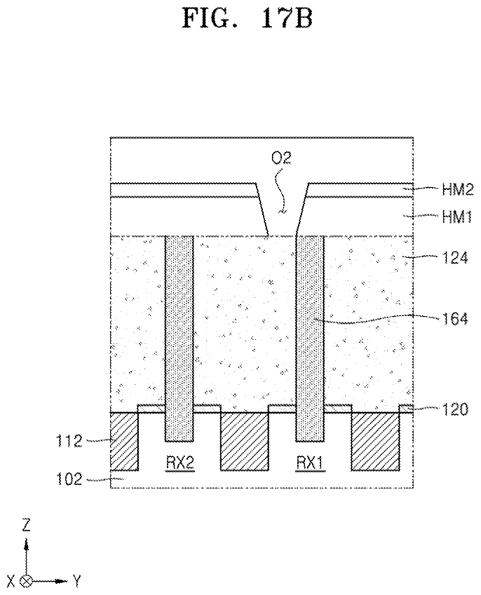

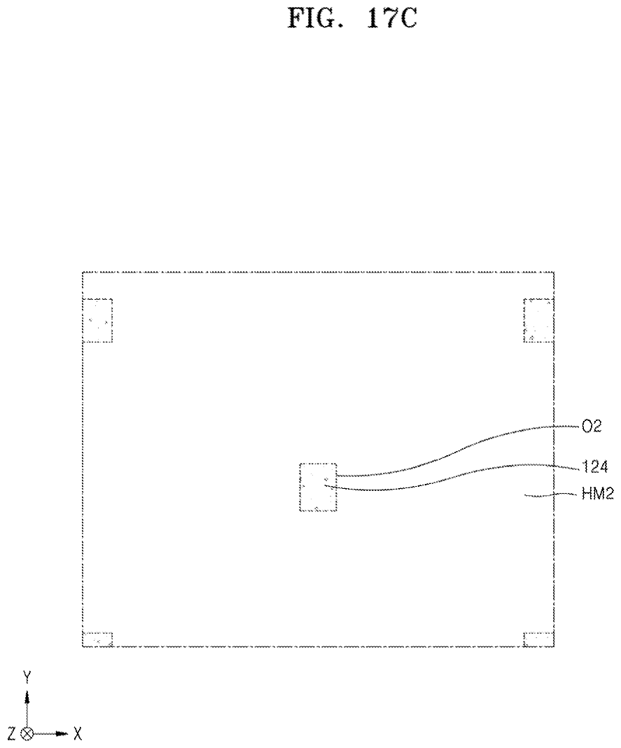

Referring to FIGS. 16A, 16B, and 16C, from the result of FIG. 15, after sequentially forming first to third hard mask layers HM1, HM2, and HM3 on an upper surface of each of the second sacrificial insulating layer 124, the plurality of dummy gate structures DGS, the gate spacer 118, and the second insulating pattern 164, a first mask pattern MP1 having a first opening O1 may be formed on the third hard mask layer HM3. In some embodiments, a length of the first opening O1 of the first mask pattern MP1 in the second horizontal direction (Y direction) may be adjusted. In an implementation, when the length of the first opening O1 of the first mask pattern MP1 in the second horizontal direction (Y direction) is longer than those illustrated in FIGS. 16A, 16B, and 16C, the first insulating pattern 162c of the semiconductor device 100c illustrated in FIGS. 8 and 9 may be formed through a process described below with reference to FIGS. 17A, 17B, 17C, 18A, 18B, 18C, 19A, and 19.

Referring to FIGS. 17A, 17B, and 17C, from the results of FIGS. 16A, 16B, and 16C, a second opening O2 penetrating the first hard mask layer HM1 and the second hard mask layer HM2 in the vertical direction (Z direction) may be formed by using the first mask pattern MP1 (see FIG. 16A) having the first opening O1 (see FIG. 16A), and the first mask pattern MP1 and the third hard mask layer HM3 (see FIG. 16A) may be removed.

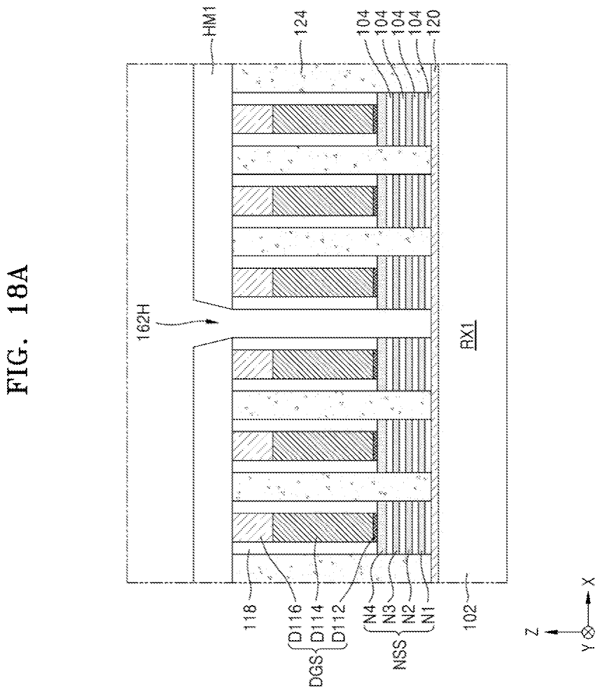

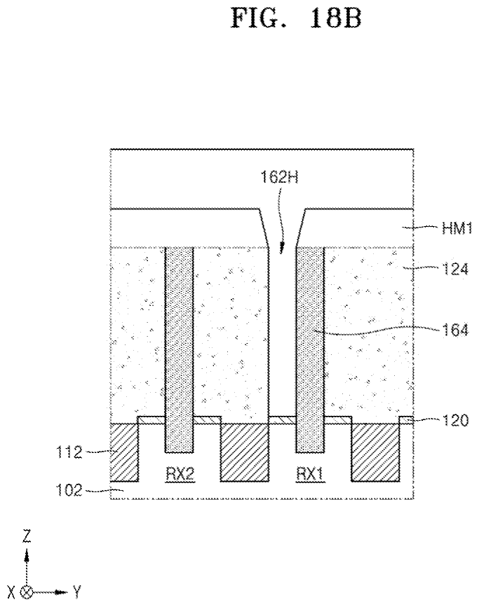

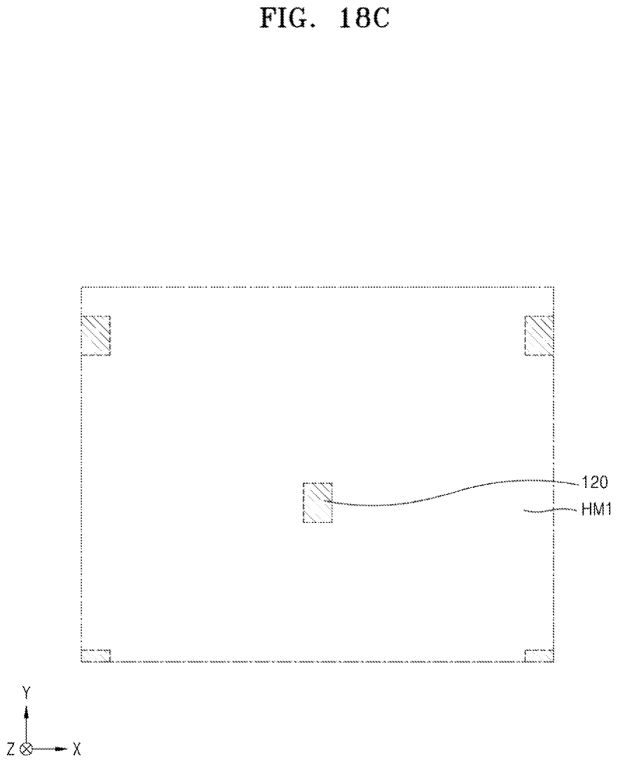

Referring to FIGS. 18A, 18B, and 18C, from the results of FIGS. 17A, 17B, and 17C, a through hole 162H penetrating the second sacrificial insulating layer 124 in the vertical direction (Z direction) may be formed by using the first hard mask layer HM1 and the second hard mask layer HM2 having the second opening O2, and the second hard mask layer HM2 (see FIG. 17A) may be removed. In some embodiments, a bottom surface of the through hole 162H may be positioned at a higher vertical level than a bottom surface of the through hole 164H (see FIG. 14A). Accordingly, the bottom surface of the first insulating pattern 162 formed in the through hole 162H may be positioned at a higher vertical level than the bottom surface of the second insulating pattern 164 formed in the through hole 164H.

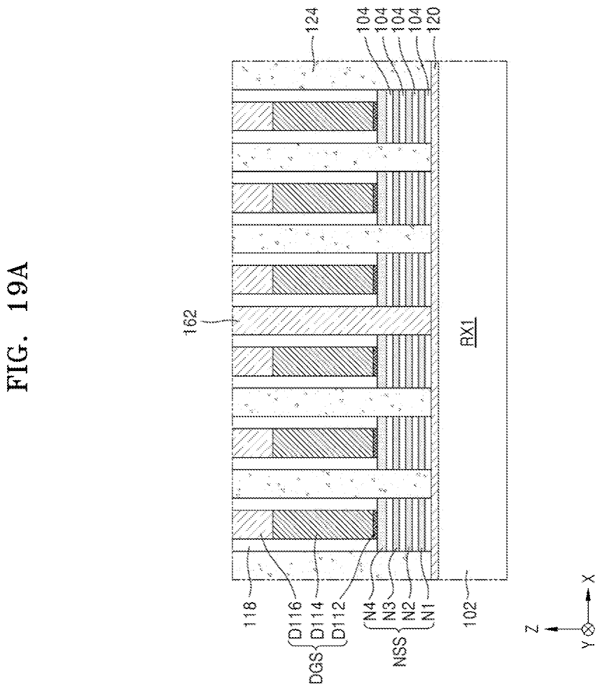

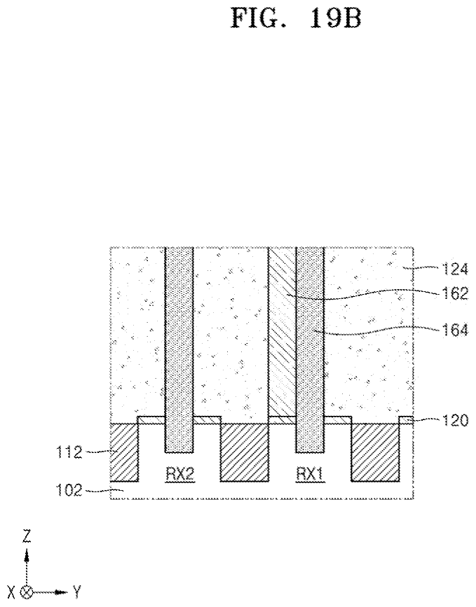

In FIGS. 18A, 18B, and 18C, the through hole 162H penetrates only the second sacrificial insulating layer 124 in the vertical direction (Z direction), but embodiments not limited thereto. In an implementation, unlike illustrated in FIGS. 18A, 18B, and 18C, the through hole 162H may penetrate a part of each of the second sacrificial insulating layer 124 and the isolation insulating layer 120 in the vertical direction (Z direction). In this case, the first insulating pattern 162a of the semiconductor device 100a illustrated in FIGS. 4 and 5 may be formed by filling the through hole 162H with an insulating material in a process to be described below with reference to FIGS. 19A and 19B. In another implementation, the through hole 162H may penetrate a part of each of the second sacrificial insulating layer 124, the isolation insulating layer 120, and the plurality of active regions RX1 and RX2 in the vertical direction (Z direction). In this case, the first insulating pattern 162b of the semiconductor device 100b illustrated in FIGS. 6 and 7 may be formed by filling the through hole 162H with the insulating material in the process to be described below with reference to FIGS. 19A and 19B.

Referring to FIGS. 19A and 19B, from the results of FIGS. 18A, 18B, and 18C, the first insulating pattern 162 may be formed by filling the through hole 162H (see FIG. 18A) with an insulating material and performing a planarization process. The first hard mask layer HM1 (FIG. 18A) may be removed through the planarization process. In some embodiments, the planarization process may be a chemical mechanical polishing (CMP) process. Through the planarization process, upper surfaces of the first insulating pattern 162 and the second insulating pattern 164 may be coplanar. That is, the upper surface of the first insulating pattern 162 and the upper surface of the second insulating pattern 164 may be positioned at substantially the same vertical level.

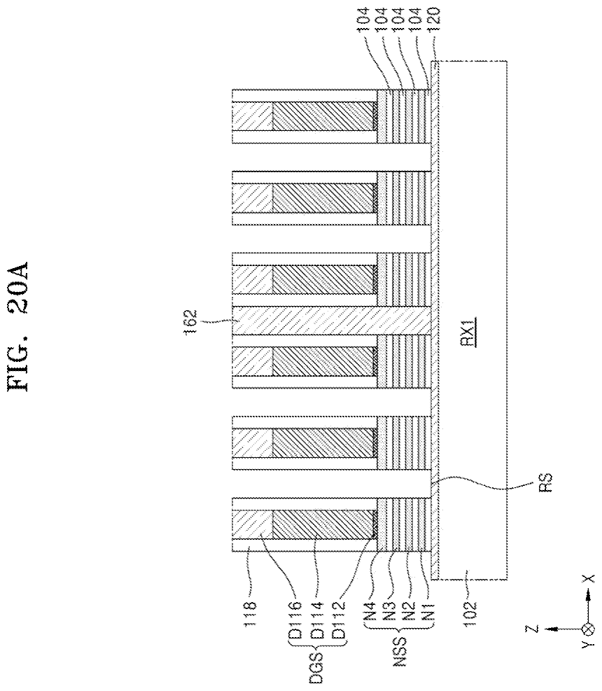

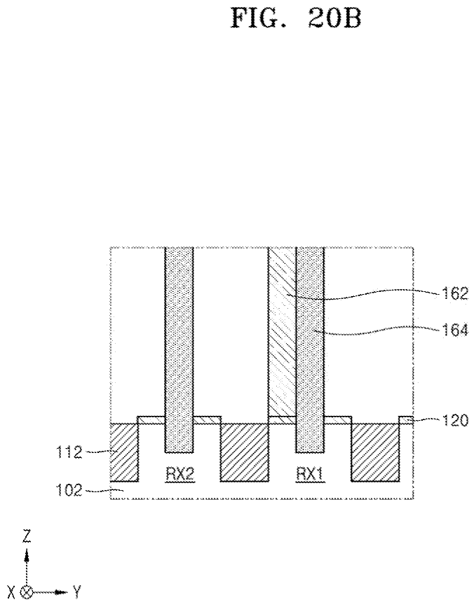

Referring to FIGS. 20A and 20B, from the results of FIGS. 19A and 19B, the plurality of recesses RS may be formed by removing the second sacrificial insulating layer 124 (see FIG. 19A). To form the plurality of recesses RS, the second sacrificial insulating layer 124 may be etched by using a wet method, a dry method, or a combination thereof.

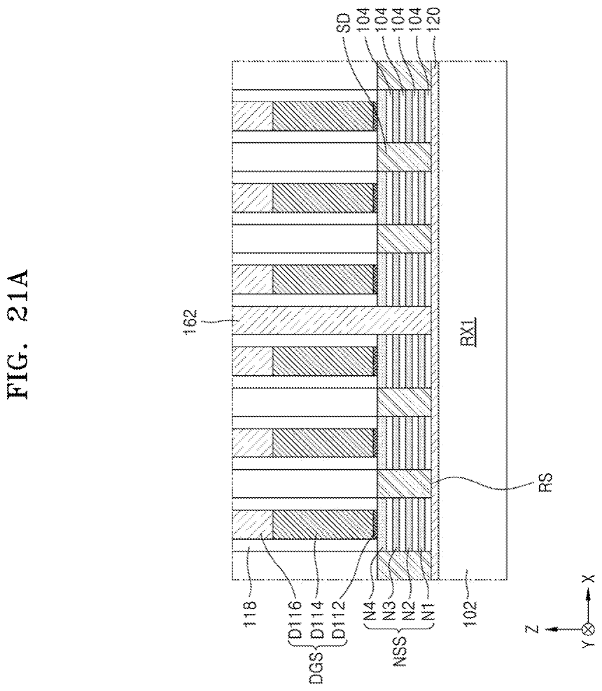

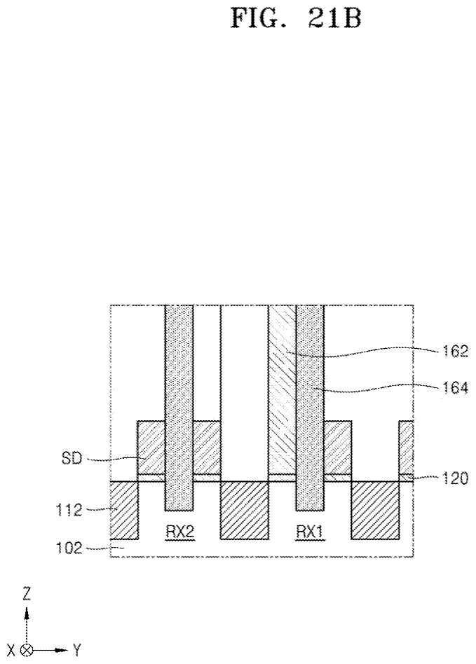

Referring to FIGS. 21A and 21B, from the results of FIGS. 20A and 20B, the plurality of source/drain regions SD may be formed on the plurality of active regions RX1 and RX2 at both sides of the plurality of nanosheet stacks NSS. To form the plurality of source/drain regions SD, a semiconductor material may be epitaxially grown from surfaces of the plurality of active regions RX1 and RX2 exposed from bottom surfaces of the plurality of recesses RS, and a sidewall of each of the first to fourth nanosheets N1 and N2, N3, N4. In some embodiments, to form a plurality of source/drain regions SD, a low-pressure chemical vapor deposition (LPCVD) process, a selective epitaxial growth (SEG) process, or a cyclic deposition and etching (CDE) process may be performed by using raw materials including an element semiconductor precursor.

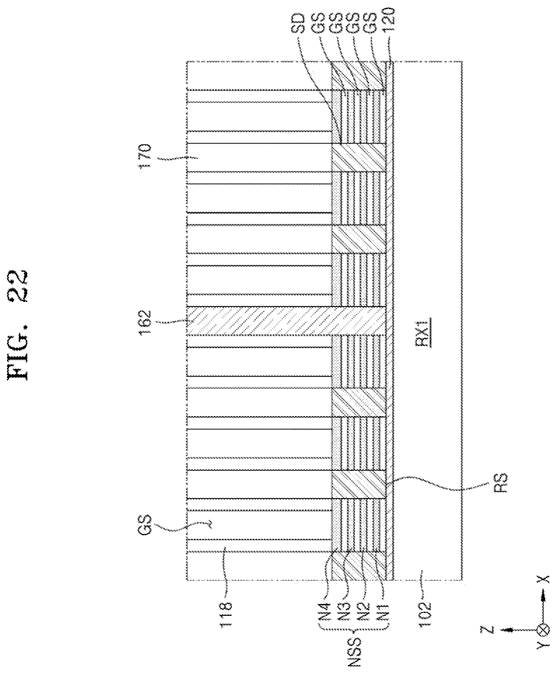

Referring to FIG. 22, from the results of FIGS. 21A and 21B, a plurality of gate spaces GS may be formed on the plurality of nanosheet stacks NSS by removing the dummy capping layer D116, the dummy gate layer D114, and the oxide layer D112 included in the plurality of dummy gate structures DGS. Next, the plurality of gate spaces GS may extend to between the plurality of nanosheets N1, N2, N3, and N4 and between the first nanosheet N1 and the upper surfaces of the plurality of active regions RX1 and RX2 by removing the plurality of sacrificial semiconductor layers 104 on the plurality of active regions RX1 and RX2 through the plurality of gate spaces GS on the plurality of nanosheet stacks NSS.

In some embodiments, to selectively remove the plurality of sacrificial semiconductor layers 104, differences in etching selectivity between the plurality of nanosheets N1, N2, N3, and N4 and the plurality of sacrificial semiconductor layers 104 may be used. A liquid or gaseous etchant may be used to selectively remove the plurality of sacrificial semiconductor layers 104. In some embodiments, to selectively remove the plurality of sacrificial semiconductor layers 104, a CH₃COOH-based etchant, In an implementation, an etchant including a mixture of CH₃COOH, HNO₃, and HF, or an etchant including a mixture of CH₃COOH, H₂O₂, and HF, may be used, but is not limited to the example above.

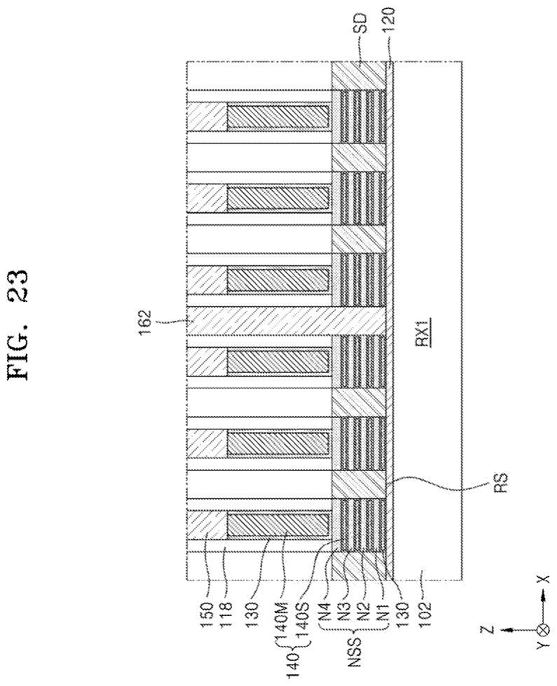

Referring to FIG. 23, from the result of FIG. 22, the gate insulating layer 130 covering exposed surfaces of the plurality of nanosheets N1, N2, N3, and N4 and the plurality of active regions RX1 and RX2 may be formed. Next, after the gate insulating layer 130 is formed, the plurality of gate lines 140 filling the remaining plurality of gate spaces GS (see FIG. 22) may be formed, and the gate capping layer 150 covering the upper surface of each of the main gate line 140M and the gate insulating layer 130 covering sidewalls of the main gate line 140M may be formed.

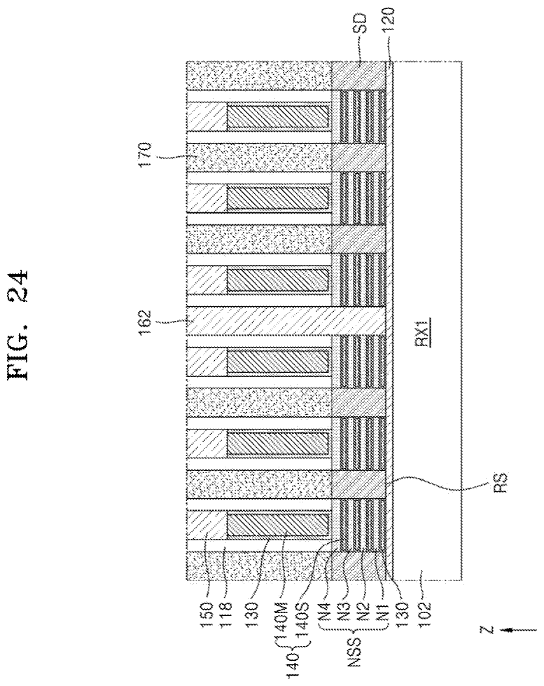

Referring to FIG. 24, from the result of FIG. 23, the inter-gate insulating layer 170 covering upper surfaces of the plurality of source/drain regions SD and surrounding the first insulating pattern 162, the second insulating pattern 164, and the gate spacer 118 may be formed.

Next, from the result of FIG. 24, the plurality of source/drain contacts CA may be formed by forming a through hole penetrating the inter-gate insulating layer 170 and filling the through hole with a conductive material, and thus, the semiconductor device 100 illustrated in FIGS. 1 to 3 may be manufactured.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present embodiments as set forth in the following claims.

What is claimed is:

1. A semiconductor device, comprising:
a substrate;
an active region protruding from an upper surface of the substrate and extending in a first horizontal direction;
a plurality of nanosheet stacks on the active region;
a plurality of gate lines on the active region and extending in a second horizontal direction intersecting the first horizontal direction, and surrounding the plurality of nanosheet stacks; and
a first insulating pattern between two nanosheet stacks adjacent in the first horizontal direction among the plurality of nanosheet stacks, on the active region, and extending in a vertical direction perpendicular to the first horizontal direction and the second horizontal direction, the first insulating pattern contacting the plurality of nanosheet stacks.

2. The semiconductor device as claimed in claim 1, wherein the entirety of the first insulating pattern overlaps the active region in the vertical direction.

3. The semiconductor device as claimed in claim 1, wherein the first insulating pattern includes silicon nitride, silicon carbonitride, silicon carbonate, or silicon carbonitride.

4. The semiconductor device as claimed in claim 1, wherein
each of the plurality of gate lines includes a main gate line and a plurality of sub gate lines, and
further includes a gate capping layer on an upper surface of the main gate line, and
an upper surface of the first insulating pattern is positioned at a same vertical level as an upper surface of the gate capping layer.

5. The semiconductor device as claimed in claim 1, further comprising a plurality of source/drain regions between the plurality of nanosheet stacks and respectively contacting the plurality of nanosheet stacks, wherein the first insulating pattern is spaced apart from the plurality of source/drain regions by the plurality of nanosheet stacks.

6. The semiconductor device as claimed in claim 1, further comprising an isolation insulating layer on an upper surface of the substrate, wherein a bottom surface of the first insulating pattern is in contact with an upper surface of the isolation insulating layer.

7. The semiconductor device as claimed in claim 6, wherein the isolation insulating layer and the first insulating pattern include different materials from each other.

8. The semiconductor device as claimed in claim 6, wherein the first insulating pattern extends into the isolation insulating layer.

9. The semiconductor device as claimed in claim 6, wherein the first insulating pattern penetrates the isolation insulating layer in the vertical direction and extends into the active region.

10. The semiconductor device as claimed in claim 1, wherein:
the first insulating pattern extends in the second horizontal direction beyond the active region in a planar view,
a part of the first insulating pattern overlaps the active region in the vertical direction, and
a remaining part of the first insulating pattern overlaps a device isolation layer surrounding both sidewalls of the active region in the vertical direction.

11. The semiconductor device as claimed in claim 10, wherein a bottom surface of the part of the first insulating pattern overlapping the active region in the vertical direction is positioned at a higher vertical level than a bottom surface of the remaining part of the first insulating pattern overlapping the device isolation layer in the vertical direction.

12. A semiconductor device, comprising:
a substrate;
an active region protruding from an upper surface of the substrate and extending in a first horizontal direction;
an isolation insulating layer on an upper surface of the active region;
a plurality of nanosheet stacks on the active region;
a plurality of gate lines extending in a second horizontal direction intersecting the first horizontal direction, on the active region, and surrounding the plurality of nanosheet stacks;
a first insulating pattern between two nanosheet stacks adjacent in the first horizontal direction among the plurality of nanosheet stacks, on the active region, and extending in a vertical direction perpendicular to the first horizontal direction and the second horizontal direction, the first insulating pattern in contact with the plurality of nanosheet stacks; and
a second insulating pattern extending in the first horizontal direction on the active region.

13. The semiconductor device as claimed in claim 12, wherein the first insulating pattern is in contact with the second insulating pattern.

14. The semiconductor device as claimed in claim 12, wherein a bottom surface of the first insulating pattern is positioned at a higher vertical level than a bottom surface of the second insulating pattern.

15. The semiconductor device as claimed in claim 12, wherein an upper surface of the first insulating pattern is positioned at a same vertical level as an upper surface of the second insulating pattern.

16. The semiconductor device as claimed in claim 12, wherein the first insulating pattern and the second insulating pattern each include silicon nitride, silicon carbonitride, silicon carbonate, or silicon carbonitride.

17. The semiconductor device as claimed in claim 12, wherein the first insulating pattern and the second insulating pattern include different materials from each other.

18. A semiconductor device, comprising:
a substrate;
an active region protruding from an upper surface of the substrate and extending in a first horizontal direction;
a device isolation layer surrounding both sidewalls of the active region;
an isolation insulating layer on an upper surface of the active region;
a plurality of nanosheet stacks spaced apart from the upper surface of the active region;
a plurality of gate lines extending in a second horizontal direction intersecting the first horizontal direction, on the active region, and surrounding the plurality of nanosheet stacks;
a plurality of source/drain regions between the plurality of nanosheet stacks, on the active region, and contacting the plurality of nanosheet stacks;
a first insulating pattern between two nanosheet stacks adjacent in the first horizontal direction among the plurality of nanosheet stacks, on the active region, and extending in a vertical direction perpendicular to the first horizontal direction and the second horizontal direction, the first insulating pattern being in contact with the plurality of nanosheet stacks and spaced apart from the plurality of source/drain regions; and
a second insulating pattern extending in the first horizontal direction, on the active region, and at least partially penetrating the plurality of gate lines, the isolation insulating layer, and the active region, in the vertical direction.

19. The semiconductor device as claimed in claim 18, wherein a bottom surface of the first insulating pattern is positioned at a same or lower vertical level than an upper surface of the isolation insulating layer.

20. The semiconductor device as claimed in claim 18, wherein at least a part of the first insulating pattern overlaps the active region in the vertical direction.
